(19) United States
(12) Patent Application Publication
(10) Pub. No.: US 2019/0329576 A1
(43) Pub. Date: Oct. 31, 2019

(54) GRAVURE-PRINTED DEVICES AND METHOD OF PRODUCING SUCH DEVICES

(71) Applicant: CCL Secure Pty Ltd., Craigieburn, Victoria (AU)

(72) Inventor: Karlo Ivan Jolic, Craigieburn, Victoria (AU)

(73) Assignee: CCL Secure Pty Ltd, Craigieburn, Victoria (AU)

(21) Appl. No.: 16/310,307

(22) PCT Filed: Jun. 22, 2017
(86) PCT No.: PCT/AU2017/050636

§ 371 Date: Dec. 14, 2018

(30) Foreign Application Priority Data
Jun. 22, 2016 (AU) 2016100918

(51) Int. Cl. B41M 1/10; B41M 3/14; B42D 25/324; B42D 25/351; B41F 3/36; B41F 9/00; B42D 25/29

(52) U.S. Cl. CPC B41M 1/10; B41M 3/14; B42D 25/324; H05K 2203/0143; B41F 3/36; B41F 9/00; B42D 25/29; B42D 25/351

(57) ABSTRACT

A method of printing a discontinuous image on a device using a gravure printing process which is susceptible to feathering, the device including: a substrate, and an image layer superposed with at least a portion of the substrate, the image layer including the discontinuous image, the discontinuous image having at least one leading edge during printing, the method including: printing a plurality of anti-feathering elements in an extended edge region of the image layer adjacent the leading edge, the anti-feathering elements being printed before the leading edge of the discontinuous image, the anti-feathering elements and discontinuous image being printed in the same rotary action, wherein the plurality of anti-feathering elements are indiscernible to the naked eye.

### TECHNICAL FIELD

The invention relates generally to gravure-printed devices and methods for producing such devices. The invention is applicable to the printing of a discontinuous image on a micro-optic device using a gravure printing process which is susceptible to feathering, such as micro-optic devices used in the manufacture of bank notes and like security documents. It will be convenient to describe the invention in relation to that exemplary, but non-limiting application.

### BACKGROUND OF INVENTION

It is well-known that many of the world's bank notes, as well as other security documents, bear micro-optic devices that produce optical effects enabling a visual authentication of the bank note. Some of these micro-optic devices include focusing elements, such as micro-lenses, which act to sample image elements and project imagery which is observable to a user for authentication purposes. Other image elements may be incorporated into the bank note design to assist in authentication of the bank note.

These image elements may be printed onto a surface during production of the bank note using a rotary printing process, for example gravure printing. However, portions of these printed image elements may suffer from distortion known as “feathering”.

Feathering can be caused by a number of factors. For example, some of the ink from the printing drum drying more than expected before it is applied to a printing surface, for example a paper or polymer surface. Feathering can also be caused by the indentations intended to fill with ink, such as gravure cells on the leading edge (the edge first printed on the printing surface) of an image to be applied on the printing surface not filled with ink as expected. Another possible cause is the indentations on the leading edge not transferring the ink contained within the cells to the printing surface as expected. Again, this can be an issue with gravure cells during gravure printing. In general, any distortion that results in an edge of the image that appears ragged or feathered, and is therefore less well-defined than expected, may be described as a “feathering” effect. The feathering effect is usually associated with the leading edge of the image.

It would be desirable to provide a micro-optic device and/or method of manufacturing a micro-optic device that minimise the effect of feathering.

It would also be desirable to provide a micro-optic device and/or method of manufacturing a micro-optic device that ameliorates or overcomes one or more disadvantages or inconveniences of known micro-optic devices.

### SUMMARY OF INVENTION

One aspect of the invention provides a method of printing a discontinuous image on a device using a gravure printing process which is susceptible to feathering, the device including

a substrate, and
an image layer superposed with at least a portion of the substrate, the image layer including the discontinuous image, the discontinuous image having at least one leading edge during printing,
the method including:
printing a plurality of anti-feathering elements in an extended edge region of the image layer adjacent to the leading edge,
wherein the plurality of anti-feathering elements are indiscernible to the naked eye.

In one or more embodiments, the discontinuous image has a plurality of leading edges during printing. In this case, the method may further include printing a plurality of anti-feathering elements in each of the extended edge regions. Each extended edge region being adjacent a different one of the leading edges, the anti-feathering elements in each extended edge region being printed before an adjacent leading edge of the discontinuous image.

In one or more embodiments, one or more of the plurality of leading edges may be within the discontinuous image.

In order that the plurality of anti-feathering elements are indiscernible to the naked eye, in one or more embodiments, the anti-feathering elements may have at least one dimension less than 200 microns.

In one or more embodiments, the plurality of ant-feathering elements each have at least one dimension less than 100 microns and preferably between 30 and 50 microns. For example, the anti-feathering elements may be lines or other elongate shapes.

In one or more other embodiments, all dimensions of the plurality of anti-feathering elements may be less than 100 microns and preferably between 30 and 50 microns. For example, the anti-feathering elements may be dots or other shortened shapes.

In one or more embodiments, the print density of the anti-feathering elements in the extended edge regions may be such that the anti-feathering elements up to 15% of each extended edge region.

In one or more embodiments, the anti-feathering elements may be arranged in geometric groupings. For example, rectangular, hexagonal or like patterns of anti-feathering elements.

In one or more embodiments, the device further includes a first opacification layer superposed with at least a portion of the substrate. The first opacifying layer having a window revealing the discontinuous image. In these embodiments, the method may further include printing the image layer and the first opacifying layer in a same rotary printing action, for example, using the same gravure cylinder. The image layer and first opacifying layer being formed on a first side of the substrate from the same printed material.

Alternatively, the micro-optic device may further include a first opacification layer superposed with at least a portion of the substrate and the method may further include printing the image layer and the first opacifying layer in separate rotary printing actions. The image layer and the first opacifying layer being formed on a first side of the substrate from different printed materials.

In one or more embodiments, the image layer and the first opacifying layer may be in different planes. In other embodiments though, the image layer and the first opacifying layer may be coplanar.

The image layer and the first opacifying layer may be formed from different coloured printed material.

In one or more embodiments, the first opacifying layer may include a window revealing the discontinuous image.

In some embodiments, the method may further include printing a second windowless opacifying layer over the image layer and the first opacifying layer, so that the discontinuous image is only visible in the window when viewed through the substrate. In this case, the second windowless opacifying layer may be substantially opaque to allow negligible transmission of visible light. If the second windowless opacifying layer is insufficiently opaque, the opacity can be increased by adding further opacifying layers on top of the second windowless opacifying layer.

The method may further include forming focusing elements in or on the substrate. The focusing elements causing the image elements to be sampled so as to project imagery which is observable to a user from at least a first viewing angle, wherein the plurality of anti-feathering elements in each extended edge region include design parameters selected to minimise moiré magnification effects when sampled by the focusing elements.

In one or more embodiments, the anti-feathering elements are arranged in random positions.

In other embodiments, the focusing elements may be a geometric array of lenses, and the anti-feathering elements may be arranged in a geometric pattern. The period of the anti-feathering elements and the period of the lenses and the relative angle of the anti-feathering element pattern and the lens pattern being selected so that the period of corresponding moiré fringes is indiscernible to the naked eye.

In one or more embodiments, the device is a micro-optic device for producing optical effects and the substrate is transparent or translucent.

Another aspect of the invention provides a device including a discontinuous image printed using a gravure printing process which is susceptible to feathering, the device including:

a substrate, and
an image layer superposed with at least a portion of the substrate, the image layer including a discontinuous image, the discontinuous image having at least one leading edge during printing,
the method including:
printing a plurality of anti-feathering elements in an extended edge region of the image layer adjacent to the leading edge,
wherein the plurality of anti-feathering elements are indiscernible to the naked eye.

Yet another aspect of the invention provides a security document including a device as described above.

### Definitions

### Security Document or Token

As used herein, the terms security documents and tokens includes all types of documents and tokens of value and identification documents including, but not limited to the following: items of currency such as bank notes and coins, credit cards, cheques, passports, identity cards, securities and share certificates, driver's licenses, deeds of title, travel documents such as airline and train tickets, entrance cards and tickets, birth, death and marriage certificates, and academic transcripts.

The invention is particularly, but not exclusively, applicable to security devices, for authenticating items, documents or tokens, such as bank notes, or identification documents, such as Identity cards or passports, formed from a substrate to which one or more layers of printing are applied.

More broadly, the invention is applicable to a micro-optic device which, in various embodiments, is suitable for visual enhancement of clothing, skin products, documents, printed matter, manufactured goods, merchandising systems, packaging, point of purchase displays, publications, advertising devices, sporting goods, security documents and tokens, financial documents and transaction cards, and other goods.

### Security Device or Feature

As used herein, the term security device or feature includes any one of a large number of security devices, elements or features intending to protect security document or token from counterfeiting, copying, alteration or tampering. Security devices or features may be provided in or on the substrate of the security document or in or on one or more layers applied to the base substrate, and may take a wide variety of forms such as security threads embedded in layers of the security document; security inks such as fluorescent, luminescent or phosphorescent inks, metallic inks, iridescent inks, photochromic, thermochromic, hydrochromic, or piezochromic inks; printed or embossed features including release structures; interference layers; liquid crystal devices; lenses and lenticular structures; optically variable devices (OVDs) such as diffractive devices including diffraction gratings, holograms and diffractive optical elements (DOEs).

### Substrate

As used herein, the term substrate refers to the base material from which the security document or token is formed. The base material may be paper or other fibrous materials such as cellulous; a plastic or polymeric material including but not limited to polypropylene (PP), polyethylene (PE), polycarbonate (PC), polyvinyl chloride (PVC), polyethylene terephthalate (PET), biaxially-oriented polypropylene (BOPP); or a composite material of two or more materials, such as a laminate of paper and at least one plastic material, or of two or more polymeric materials.

### Transparent Windows and Half Windows

As used herein, the term window refers to a transparent or translucent area in the security document compared to the opaque region to which printing is applied. The window maybe fully transparent so as to allow the transmission of light substantially unaffected, or it may be partly transparent or translucent, partly allowing the transmission of light but without allowing objects to be seen clearly through the window area.

A window area may be formed in a polymeric security document which has at least one layer of transparent polymeric material and one or more opacifying layers applied to at least one side of a transparent polymeric substrate, by omitting at least one opacifying layer in the region forming the window area. If opacifying layers are applied to both sides of a transparent substrate, a fully transparent window may be formed by omitting the opacifying layers on both sides of the transparent substrate in the window area.

A partly transparent or translucent area herein after referred to as a “half window”, may be formed in a polymeric security document which has opacifying layers on both sides by omitting the opacifying layers on one side only of the security document in the window area so that “half-window” is not fully transparent but allows sunlight to pass through without allowing objects to be viewed clearly through the half window.

Alternatively, it is possible for the substrates to be formed from a substantially opaque material, such as paper or fibrous material, with an insert of transparent plastics material inserted into a cut out or recessed into the paper or fibrous substrate to form a transparent window or a translucent half-window area.

### Opacifying Layers

One or more opacifying layers may be applied to a transparent substrate to increase the opacity of the security document. An opacifying layer is such that LT<L0 where L0 is the amount of light incident on the document, and LT is the amount of light transmitted through the document. An opacifying layer may comprise any one or more of a variety of opacifying coatings. For example, the opacifying coatings may comprise a pigment, such as titanium dioxide, dispersed within a binder or carrier of heat-activated cross-linkable polymeric material. Alternatively, a substrate of transparent plastic material could be sandwiched between opacifying layers of paper or other partially or substantially opaque material to which indicia may be subsequently printed or otherwise applied.

### Focusing Elements

One or more focusing elements may be applied to the substrate of the security device. As used herein, the term “focusing element” refers to devices that focus light towards, or cause light to be diverged from or constructively interfere at a real or imaginary focal point. Focusing elements include refractive lenses that focus incoming light to a real focal point in a real focal plane or to a virtual focal point in a virtual focal plane and also collimate light scattered from any point in the focal plane to a particular direction. Focusing elements also include convex reflective elements having a virtual focal point where incoming substantially collimated light appears to diverge from that single virtual focal point. Focusing elements also include transmissive or reflective diffractive lenses, zone plates and the like that cause the transmitted or reflected diffracted light to constructively interfere at a desired real or virtual focal point.

### BRIEF DESCRIPTION OF DRAWINGS

Preferred embodiments of the invention will now be described by way of example only with reference to the accompanying drawings in which:

FIG. 1 is a schematic diagram of one embodiment of an apparatus for in-line manufacturing of part of a security document;

FIG. 2 is a cutaway side view of a partially manufactured security document manufactured by the apparatus of FIG. 1;

FIG. 3 is a plan view showing discontinuous images forming part of the printed layer of the partially manufactured security document shown in FIG. 2;

FIGS. 4 and 5 depict discontinuous images including image elements intended to be sampled by focusing elements forming part of the partially manufactured security device shown in FIG. 2, respectively without and with anti-feathering elements being printed in one or more extended edge regions of the discontinuous image;

FIGS. 6 and 7 depict exemplary discontinuous images including image elements intended to be sampled by focusing elements forming part of the partially manufactured security document shown in FIG. 2, as well as anti-feathering elements printed in one or more extended edge regions, and an opacification layer including a window portion through which the image elements can be sampled;

FIGS. 8 to 10 depict three steps in the manufacture of a security device in which a discontinuous image including a plurality of image elements and anti-feathering elements being provided in one or more extended edge regions of the discontinuous image are formed between two opacifying layers, one of which includes a window element;

FIG. 11 is a depiction of the result of the three steps shown in FIGS. 8 to 10;

FIG. 12 is a variant to the final result shown in FIG. 11, wherein the window element exactly matches the dimensions of the image elements forming the discontinuous image; and

FIGS. 13 and 14 are exploded views of two embodiments of micro-optic devices for use in the security document shown in FIG. 2.

### DETAILED DESCRIPTION OF DRAWINGS

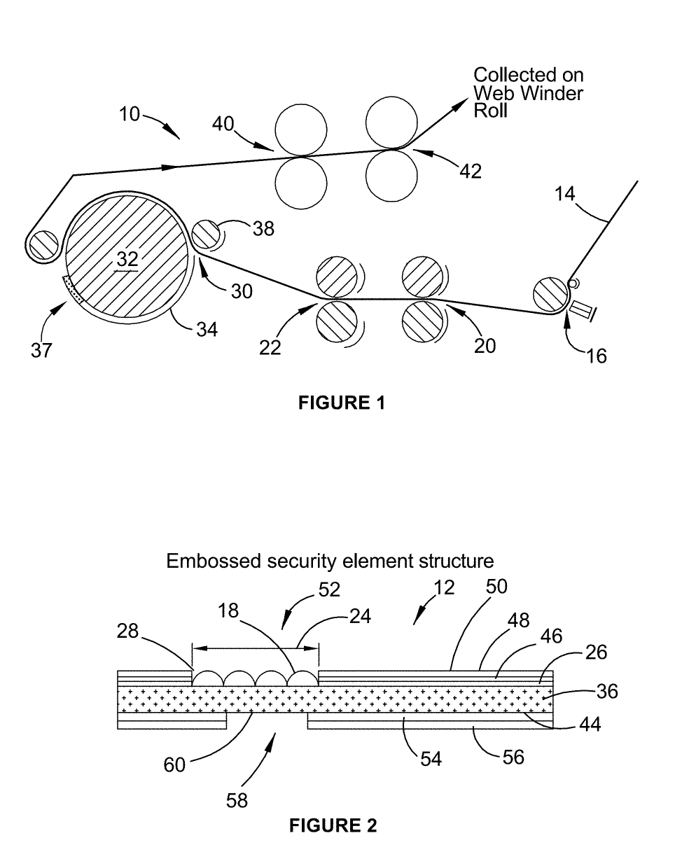

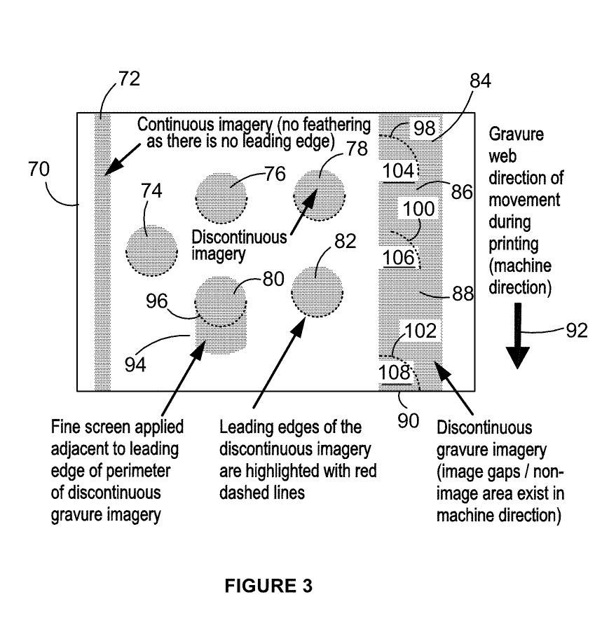

FIG. 1 shows an exemplary apparatus 10 for in-line manufacturing part of an exemplary document 12 depicted in FIG. 2. A continuous web 14 of translucent or transparent material such as polypropylene or PET is subject to an adhesion promoting process at a first processing station 16 including a roller assembly. Suitable adhesion promoting processes include flame treatment, corona discharge treatment, plasma treatment or similar.

An adhesion promoting layer is applied at a second processing station 20 including a roller assembly. A suitable adhesion promoting layer is one specifically adapted for the promotion of an adhesion of UV-curable coatings to polymeric surfaces. The adhesion promoting layer may have a UV curing layer, a solvent-based layer, a water-based layer or any combination of these.

At a third processing station 22 which also includes a roller assembly, the radiation sensitive coating is applied to the surface of the adhesion promoting layer. The radiation sensitive coating can be applied via flexographic printing, gravure printing or a silk screen printing process and variations thereof amongst other printing processes.

The radiation sensitive coating is only applied to the security element area 24 on a first surface 26 where a structure 28 including a periodic array of lens elements is to be positioned. The security element area 24 can take the form of a stripe, a discrete patch in the form of simple geometric shape or in the form of a more complex graphical design.

While the radiation sensitive coating is still, at least partially, liquid, it is processed to form the structure 28 at a fourth processing station 30. In one embodiment, the processing station 30 includes an embossing roller 32 for embossing a security element structure, such as the structure 28 into a radiation sensitive coating in the form of a UV-curable ink. The cylindrical embossing surface 34 has surface relief formations corresponding to the shape of the structure 28 to be formed. In one embodiment, the surface relief formations can orient the array of lens elements in the machine direction, transverse to the machine direction, or in multiple directions at an angle to the machine direction. The apparatus 10 can form micro lenses in a variety of shapes.

The cylindrical embossing surface 34 of the embossing roller 32 may have a repeating pattern of surface relief formations or the relief structure formations may be localized to individual shapes corresponding to the shape of the security elements area 24 on the substrate 36. The embossing roller 32 may have the surface relief formations formed by a diamond stylus of appropriate cross section, or by direct laser engraving or chemical etching, or the surface relief formations may be provided by at least one embossing shim 37 provided on the embossing roller 32. The at least one embossing shim may be attached via adhesive tape, magnetic tape, clamps or other appropriate mounting techniques.

The UV-curable ink on the substrate is brought into intimate contact with the cylindrical embossing surface 34 of the embossing roller 32 by a roller 38 at processing station 30 such that the liquid UV-curable ink flows into the surface relief formations of the cylindrical embossing surface 34. At this stage, the UV-curable ink is exposed to UV radiation, for example, by transmission through the substrate layer 36.

With the security element structure 28 applied to the document substrate 36, one or more additional layers are applied at a downstream processing station including further roller assemblies 40 and 42. The additional layers may be clear or pigmented coatings and applied as partial coating, as a contiguous coating or accommodation of both. In one preferred method, the additional layers are opacifying layers which are applied to one or both surfaces of the substrate 36 except in the region of the security element structure.

FIG. 2 shows a partially manufactured security document formed with an embossed security element structure 28 in the form of an array of lens elements. These security documents comprise a transparent substrate of polymeric material, preferably by an axially orientated polypropylene (BOPP) having a first surface 26 and a second surface 44. Opacifying layers 46, 48 and 50 are applied to the first surface 26, except a window area 52 where the security element structure 28 is applied to the first surface 26.

Opacifying layers 54 and 56 are applied to the second surface 44 except in a window area 58. The window area 58 substantially coincides with the window area 52 on the first surface 26. A printed layer 60 may be applied to the second surface 44 on the opposite side of the substrate in the window area 58.

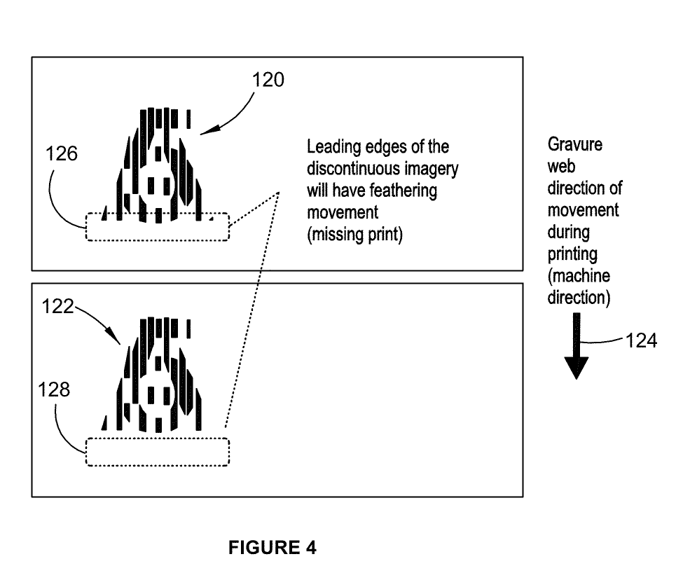

FIG. 3 depicts a portion 70 of the partially processed web 14 at the downstream processing station which includes roller assemblies 40 and 42. The roller assemblies 40 and/or 42 are used to apply an image layer including an exemplary continuous imagery 72 and discontinuous imagery 74 to 84. The continuous imagery 72 includes a continuous stripe printed on one side of the partially processed web. The discontinuous imagery 74 to 82 consists of solid discs 74 to 82, as well as a continuous stripe 84 printed along the opposite side of the web to the stripe 72 and including image gaps 86 to 90 in the stripe 84. The imagery 72 to 84 is, in this example, gravure printed in the direction indicated by the arrow 92. It will be appreciated however that in other embodiments, the continuous and discontinuous imagery may be printed using other rotary printing processes such as offset and flexography.

It can be seen in FIG. 3 that the discontinuous images 76 to 82 and the discontinuous imagery created by the presence of the gaps 86 to 90 in the printed stripe 84 all include leading edges (represented by the dotted lines) during printing. In this context, the leading edge is the portion of the discontinuous imagery that is first printed in the gravure rotary printing process. In conventional gravure printing processes, feathering is likely to occur along the leading images of the depicted discontinuous images for the reasons explained previously. In order to address this issue, anti-feathering elements may be printed in an extended edge region adjacent each leading edge where the anti-feathering elements are printed before the leading edge of the discontinuous image.

In the example depicted in FIG. 3, an extended region 94 is shown adjacent the leading edge 96 of the discontinuous image 80. The discontinuous images formed by the gaps 86 to 88 in the printed stripe 84 also include leading edges referenced 98 to 102. In this example, extended edge regions 104, 106 and 108 (corresponding to the gaps 86 to 90) are respectively adjacent to the leading edges 98 to 102.

The anti-feathering elements printed in each of the extended edge regions 94, 104, 106 and 108 are indiscernible to the naked eye. In this way, feathering is removed from the discontinuous images 80 and 84 into the extended edge regions. Extended edge region 94 has a leading edge therefore feathering will occur along its leading edge. Extended edge regions 104, 106 and 108 have no leading edge therefore they have no feathering. However, because the anti-feathering elements are not able to readily discernible with the naked eye, the feathering on the leading edge of extended edge region 94 is unable to be easily perceived by an observer.

The anti-feathering elements may typically be dots, hexagons or other regular or irregular non-elongate (shortened) shapes having parameters such as size, printing density and colour or tone that are selected so that the anti-feathering elements are indiscernible to the naked eye. In one embodiment, the anti-feathering elements can be printed dots having a diameter of approximately 30 microns and sufficiently spaced apart so that the dots cover up to 15% of at least the extended edge regions.

It will be appreciated that the anti-feathering elements may be printed to cover more than the extended edge regions adjacent a leading edge of each discontinuous image, and could cover a region as large as the full area of the bank note or security document in question. The “grid” or array of anti-feathering elements could even extend all of the way around a gravure cylinder circumference, or could even fill window or half-window areas of a bank note or other security documents. The array of anti-feathering elements could even overlap or cover areas of a bank note or other security document carrying micro-optical effect imagery. If the array of anti-feathering elements is contiguous in the machine direction and preferably contiguous around the gravure cylinder circumference, this would mean that there would be no feathering present anywhere in the contiguous array area because a uniform tone or colour would be produced within that area.

In the case of dots, hexagons or other shortened regular or irregular shapes, other dimensions (width, breadth) are preferably less than 100 microns and even more preferably between 30 and 50 microns. The dots should be sufficiently spaced so that they cannot easily be observed with the naked eye. For example, an average spacing of 80 to 100 microns has been found to be suitable for use in bank notes or like security documents. Preferably the anti-feathering elements cover up to 15% of each region in which they are printed.

In other embodiments, patterns or geometries other than dots, hexagons or other shortened shapes can be used. For example, patterns of lines arranged in regular or irregular grids can be used, provided the proportion of the substrate area covered with the line printing is sufficiently low. In this way, any change in the perceived colour of the substrate in the region of the extended edge area is sufficiently minor for the anti-feathering elements to be indiscernible to the naked eye. Where the anti-feathering elements are lines or other elongate shapes, it is preferable if the anti-feathering elements have at least one dimension less than 100 microns and more preferably have at least one dimension between 30 and 50 microns.

More generally, parameters of the anti-feathering elements, such as size, shape, pattern type, pattern spacing, can be selected so that the anti-feathering elements merely provide a minor colour change in the substrate—preferably one that is indiscernible to the naked eye. In some embodiments, “large” anti-feathering elements that are coarsely spaced and having at least one dimension up to 200 microns could be used.

In various embodiments, the anti-feathering elements may be arranged in geometric groupings. For example, patterns of lines or dots arranged in regular or irregular linear, rectangular or hexagonal grids.

The dots, lines or other anti-feathering elements may be of fixed dimensions or of variable dimensions, or of fixed shapes or variable shapes and may be positioned on a regular or irregular array or in an arrangement in which some element of randomness has been introduced.

The discontinuous images shown in FIG. 3 can be visible through a window or half-window feature of a security document or can form part of a printed design found elsewhere on the banknote. In this case, the discontinuous images may be intended for viewing by the naked eye only. However in other embodiments, the discontinuous images may include a number of image elements and be intended to form part of a security device in which lenticular lenses or other focusing elements cause the image elements to be sampled so as to project imagery which is observable to a user from at least a first viewing angle. In this case, the feathering effect intend to be addressed by the invention is more prominent.

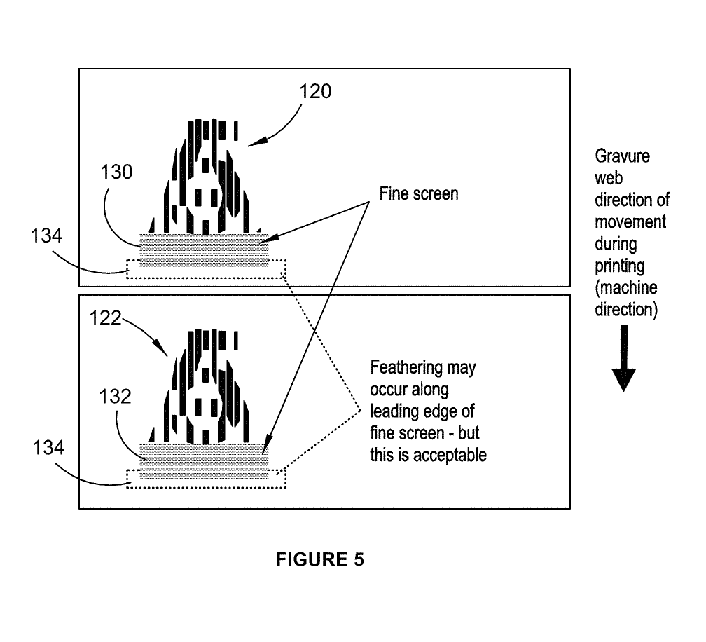

FIG. 4 depicts two discontinuous images 120 and 122 intended to be sampled by a one-dimensional array of lenticular lenses formed on an opposite side of the transparent or translucent substrate. The discontinuous images 120 and 122 are two-frame interlaced lenticular flip images (where the micro-optically magnified image flips from the letter “A” to the numeral “5” when the viewing angle is changed) and are printed consecutively when a gravure roll assembly rotates in the direction indicated by the arrow 124. Since the bank note substrate is so thin (compared to conventional lenticular image products such as lenticular postcards, for example) the smallest printed feature size of the bank note lenticular image is correspondingly very small. This, together with the fact that the unprinted image distance in the direction 124 from one discontinuous image to the next is very large means that the feathering effect is very likely to occur and the quality of the affected imagery which is observable to a user from at least a first viewing angle, will be compromised along the leading edge 126 and 128 respectively of the discontinuous images 120 and 122.

However, as seen in FIG. 5, printing anti-feathering elements in extended edge regions 130 and 132 respectively adjacent to the leading edges to the discontinuous images 120 and 122, address image degradation by displacing the feathering to the leading edges 134 and 136 respectively of the extended edge regions 130 and 132. Since the anti-feathering elements are indiscernible to the naked eye, the image quality of the discontinuous images 120 and 122 is preserved.

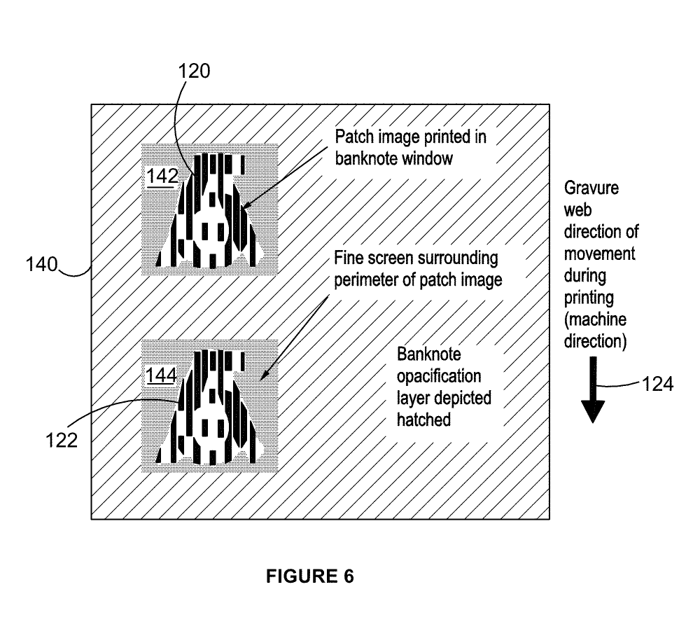

In a further embodiment shown in FIG. 6, the discontinuous images 120 and 122 are printed in a window of a bank note. Accordingly, in addition to an image layer including the discontinuous images 120 and 122 being printed so as to be superposed with at least a portion of the underlying substrate, the bank note also includes an opacification layer superposed with at least a portion of the substrate. The opacification layer includes, in this example, windows 142 and 144, revealing of the discontinuous images 120 and 122.

In this example, the anti-feathering elements are printed not only in an extended edge region adjacent the leading edge to the exterior of the discontinuous images 120 and 122, but are also printed adjacent the entire perimeter of the discontinuous images 120 and 122. The anti-feathering elements are printed in the same colour as the opacifying coating of the bank note. In the example shown in FIG. 6, the anti-feathering elements connect all portions of the design that would otherwise be discontinuous in the direction indicated by the arrow 124. In this embodiment, the anti-feathering elements and the discontinuous images can be printed using the same colour and the same gravure cylinder as is used to print the opacification layer 140.

FIG. 7 depicts a variant to the embodiment shown in FIG. 6. In this example, the anti-feathering elements are printed not only in extended edge regions adjacent the leading edges at the exterior of the discontinuous images 120 and 122, but at leading edges found within the exterior boundaries of the discontinuous images 120 and 122. These “interior” leading edges are found in the example depicted in FIG. 7 in the internal gaps or empty regions of the discontinuous images 120 and 122. Without printing the anti-feathering elements in these empty regions or gaps, a feathering effect is likely to occur when leading edges adjacent these empty regions or gaps are printed by the gravure roller assembly in the direction 124. In this way, each discontinuous image may have multiple leading edges during printing and anti-feathering elements may be printed in each of the extended edge regions that are adjacent the various leading edges, notably found within the discontinuous image.

Once again, the anti-feathering elements and the discontinuous images are printed in the same colour and using the same cylinder as is used to print the opacification layer 140. In other embodiments though, the anti-feathering elements and the discontinuous images may be printed in a different colour and/or using a different cylinder than that used for the printing of the opacification layer. For example, the opacification layer may be printed using white ink whilst the discontinuous images and the anti-feathering elements may be printed in red from a same cylinder.

In embodiments where the discontinuous image includes multiple image elements intended to be sampled by an array of lenticular lenses or other focusing elements to project imagery which is observable to a user from one or more viewing angles, the anti-feathering elements in each extended edge region may include design parameters selected to minimise moiré magnification effects when sampled by the focusing elements. For example, random positions may be introduced into the pattern of anti-feathering elements so that the pattern does not have a primary frequency that interacts with the frequency of the lens arrays to produce moiré fringes. Various suitable dithering algorithms are known that avoid moiré artefacts from being produced when the anti-feathering elements are sampled. For example, known algorithms producing half tone dithering such as those used in newspapers, can be used in order to ensure that no frequency is present in the anti-feathering element pattern that could interact with the lens pattern frequency to produce such moiré artefacts.

Other design parameters that can be selected to minimise moiré magnification effects when the anti-feathering elements are arranged in a grid and sampled by the lens include ensuring that the period of the anti-feathering elements and lens elements and angle of the grid pattern in which the anti-feathering elements are arranged as well as the direction in which the lenticular lens elements extend, are selected so that the period of corresponding moiré fringes is indiscernible to the naked eye. Such parameters may be determined via experiment or by using standard moiré magnification equations that allow computation of the period of the resulting moiré pattern for a given input frequency of lens elements and anti-feathering elements and for a given relative angle between the two. Such equations are known from the book series entitled “The Theory of the Moiré Phenomenon” by Isaac Amidror. Preferably the period of the lens elements and the pattern in which the anti-feathering elements are arranged, as well as the relative angles between the two, should be selected so that the resulting moiré fringe half period is either (i) larger than the largest dimension of the anti-feathering element grid on a bank note, or (ii) smaller than what can be easily discerned by the naked eye (e.g. smaller than 100 microns). This approach for avoiding moire artefacts is not limited to one-dimensional lens arrays. It may also be applied to two-dimensional lens arrays including hexagonal and rectangular packed lens arrays.

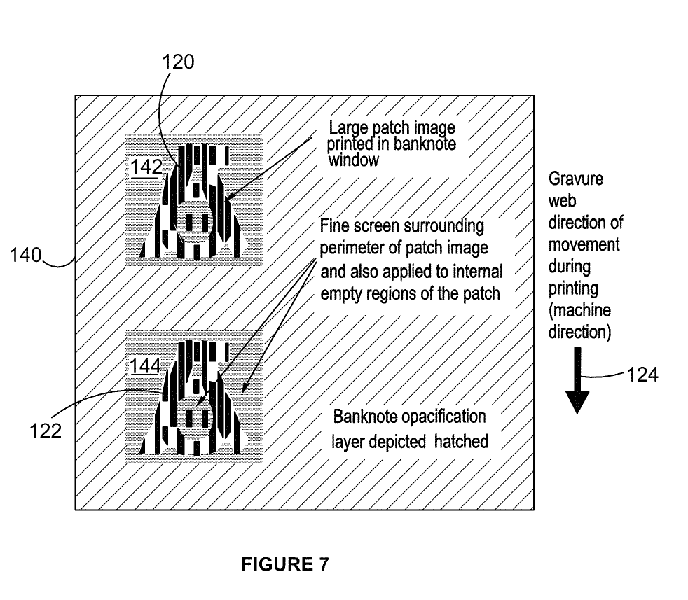

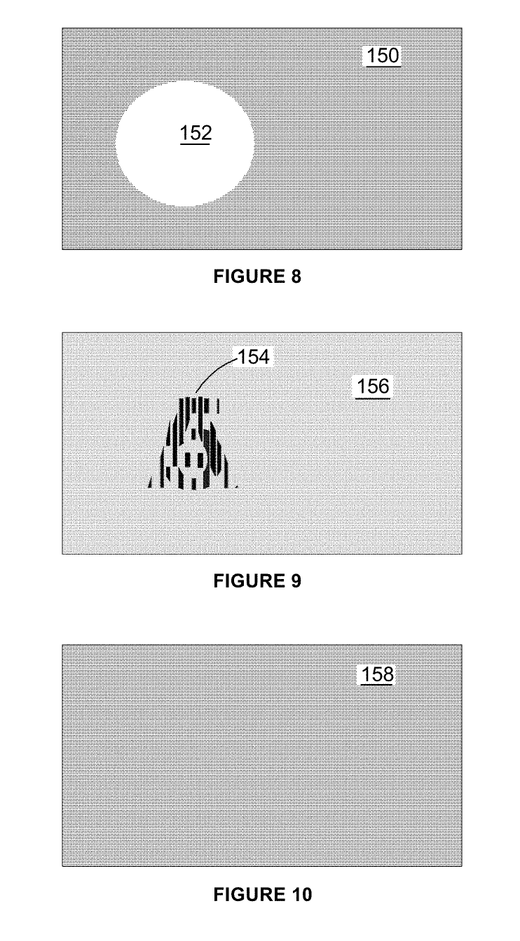

FIGS. 8 to 10 depict three steps in the manufacture an alternative embodiment to the above described embodiments, and FIG. 11 depicts the final results of that alternative embodiment. In this alternative embodiment, an opacifying layer 150 superposed with at least a portion of the substrate is firstly printed on a side of the substrate opposed to that on which the focusing elements are formed. As can be seen in FIG. 8, the opacifying layer 150 includes a window 152 intended to reveal a discontinuous image as described here above. The opacifying layer 150 may typically be printed in a light colour, for example, white.

As shown in FIG. 9, a discontinuous image 154 and surrounding anti-feathering elements 156 may be printed on top of the opacifying layer 150. This layer may be printed in a dark colour, for example, red. Although in FIG. 9 the anti-feathering elements are only shown in a region outside the discontinuous image 154, in other embodiments the anti-feathering elements may be printed in gaps inside the discontinuous image 154. A further opacifying layer 158 shown in FIG. 10 may then be printed on top of the layer shown in FIG. 9. This layer may be printed in a light colour, for example, white.

The final result is depicted in FIG. 11, which shows a view of the stacked layers when seen through the substrate. The discontinuous image 154 including multiple image elements is provided in this alternative embodiment with no feathering defects. In areas outside the window 152 formed in the opacifying layer 150, the anti-feathering elements 156 are not visible from either side of the substrate, being either covered by the opacifying layer 150 or the opacifying layer 158. Inside the window 152, the anti-feathering elements have the effect of slightly changing the background colour of the discontinuous image 154. For example, the anti-feathering elements may change the background from white to a very light shade of red.

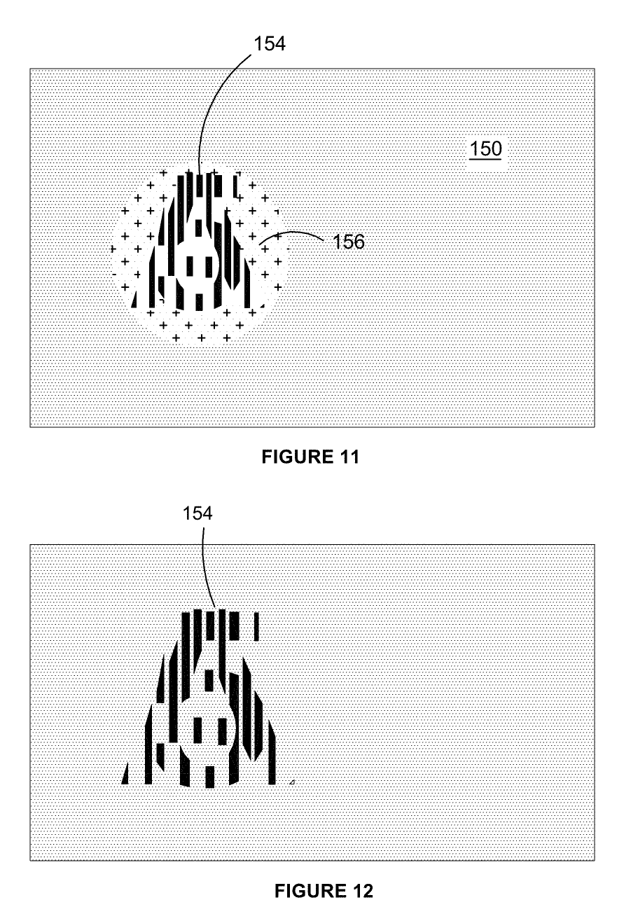

In yet another variant of the above-described embodiments, FIG. 12 depicts an arrangement identical to that shown in FIG. 11 with the exception that the window 152 has a shape that exactly matches the image elements forming part of the discontinuous image 154. In FIG. 12, it can be seen that no anti-feathering elements are visible.

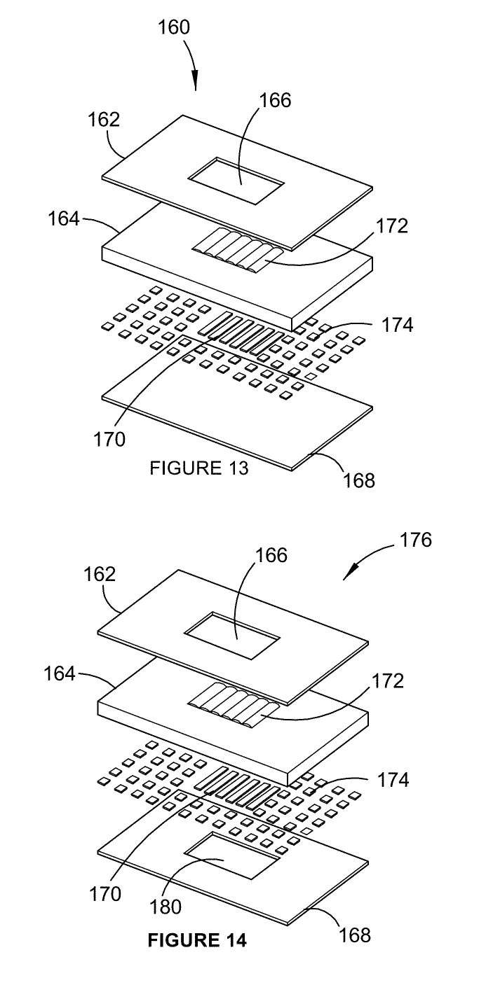

FIGS. 13 and 14 depict embodiments in which opacifying layers are applied to opposite sides of a substrate and focusing elements, in the form of a one-dimensional array of lenticular lenses, are used to sample image elements forming a discontinuous image on an opposing side of the substrate. Anti-feathering elements are applied to the substrate at the same time as the discontinuous image. In both embodiments, the discontinuous image and the anti-feathering elements are applied in a same rotary printing action.

The embodiment 160 depicted in FIG. 13 is a “half window” micro-optic device in which the opacification layer 162 printed on the substrate 164 includes a window 166, but the opacification layer 168 printed on the opposite side of the substrate 164 does not include such a window. In this case, the discontinuous image 170 of the image layer printed between the opacifying layer 168 and the substrate 164 is observable when sampled through the window 166 by the lens array 172. Feathering effects are not visible through the window 166 due to the printing of anti-feathering elements 174 printed as part of the image layer.

The embodiment 176 depicted in FIG. 14 is identical to that shown in FIG. 13 except the lower opacification layer 178 also includes a window 180 thus depicting a “full window” micro-optic device. Although the discontinuous image 170 is viewable through the window 180, the image elements forming the discontinuous image 170 only result in the projection of imagery by sampling caused by the lens array 172 when viewed through the window 166.

It will be appreciated that in some embodiments in which an opacification layer having a window is superposed with at least a portion of the substrate, the image layer consisting of the discontinuous image and anti-feathering elements and the opacifying layer may be printed in a same rotary printing action and the image layer and the opacifying layer may be formed on one side of the substrate from the same ink or other printed material. Such embodiments are depicted in FIGS. 6 and 7.

However in other of the above described embodiments, the image layer and the first opacifying layer may be printed in separate rotary printing actions and the image layer and the opacifying layer may be formed on one side of the substrate from different printed materials. Such an embodiment is depicted in FIG. 13.

In some of the above-described embodiments, the image layer and opacifying layer are coplanar. Such embodiments are shown in FIGS. 6 and 7. However in other embodiments, the opacifying layer and the image layer may be printed in different planes, such as is the case in the embodiment shown in FIGS. 13 and 14.

The lenses suitable for use in embodiments of the invention are not limited to one-dimensional lens arrays. Two-dimensional lens arrays may also be used, including hexagonal and rectangular packed lens arrays.

Whilst the above-described embodiments involve the printing of a discontinuous image on a micro-optic device, it should be understood that principles of the invention can also be applied in order to gravure print discontinuous images on devices that do not produce optical effects notably for visual authentication. For example, high resolution discontinuous images such as micro-text, high resolution pattern work, high resolution line art and high resolution tonal images with leading edges can be printed on devices including a substrate and superposed image layer. In one or more of these embodiments, the substrate need not be transparent or translucent.

Where the terms “comprise”, “comprises”, “comprised” or “comprising” are used in this specification (including the claims) they are to be interpreted as specifying the presence of the stated features, integers, steps or components, but not precluding the presence of one or more other features, integers, steps or components, or group thereof.

It will be understood that the invention is not limited to the specific embodiments described herein, which are provided by way of example only. The scope of the invention is as defined by the claims appended hereto.

The claims defining the invention are as follows:

1. A method of printing a discontinuous image on a device using a gravure printing process which is susceptible to feathering, the device including
a substrate, and
an image layer superposed with at least a portion of the substrate, the image layer including the discontinuous image, the discontinuous image having at least one leading edge during printing,
the method including:
printing a plurality of anti-feathering elements in an extended edge region of the image layer adjacent the leading edge, the anti-feathering elements being printed before the leading edge of the discontinuous image, the anti-feathering elements and discontinuous image being printed in the same rotary action,
wherein the plurality of anti-feathering elements are indiscernible to the naked eye.

2. A method according to claim 1, wherein the discontinuous image has a plurality of leading edges during printing, the method further including:
printing a plurality of anti-feathering elements in each of the extended edge regions, each extended edge region being adjacent a different one of the leading edges, the anti-feathering elements in each extended edge region being printed before an adjacent leading edge of the discontinuous image.

3. A method according to claim 2, wherein one or more of the plurality of leading edges are within the discontinuous image.

4. A method according to claim 1, wherein the anti-feathering elements have at least one dimension less than 200 microns.

5.-8. (canceled)

9. A method according to claim 1, wherein the anti-feathering elements cover up to 15% of each extended edge region.

10.-12. (canceled)

13. A method according to claim 1, wherein the device further includes a first opacification layer superposed with at least a portion of the substrate, the first opacifying layer having a window revealing the discontinuous image, the method further including:
printing the image layer and the first opacifying layer in a same rotary printing action, the image layer and the first opacifying layer being formed on a first side of the substrate from the same printed material.

14. A method according to claim 1, wherein the device further includes a first opacification layer superposed with at least a portion of the substrate, the method further including:
printing the image layer and the first opacifying layer in separate rotary printing actions, the image layer and the first opacifying layer being formed on a first side of the substrate from different printed materials.

15.-17. (canceled)

18. A method according to claim 14, wherein the first opacifying layer includes a window revealing the discontinuous image.

19. (canceled)

20. A method according to claim 1, wherein the discontinuous image includes a plurality of image elements, the method further including:
forming focusing elements in or on the substrate, the focusing elements causing the image elements to be sampled so as to project imagery which is observable to a user from at least a first viewing angle,
wherein
the plurality of anti-feathering elements in each extended edge region include design parameters selected to minimise moiré magnification effects when sampled by the focusing elements.

21.-22. (canceled)

23. A method according to claim 1, wherein the device is a micro-optic device for producing optical effects and the substrate is transparent or translucent.

24. A device including a discontinuous image printed using a gravure printing process which is susceptible to feathering, the device including
a substrate, and
an image layer superposed with at least a portion of the substrate, the image layer including a discontinuous image, the discontinuous image having at least one leading edge during printing,
the method including:
printing a plurality of anti-feathering elements in an extended edge region of the image layer adjacent the leading edge, the anti-feathering elements being printed before the leading edge of the discontinuous image, the anti-feathering elements and discontinuous image being printed in the same rotary action,
wherein the plurality of anti-feathering elements are indiscernible to the naked eye.

25. A device according to claim 24, wherein the discontinuous image has a plurality of leading edges during printing, the device further including:
a plurality of anti-feathering elements printed in each of the extended edge regions, each extended edge region being adjacent a different one of the leading edges

26. A device according to claim 25, wherein one or more of the plurality of leading edges are within the discontinuous image.

27. A device according to claim 24, wherein the anti-feathering elements have at least one dimension less than 200 microns.

28.-31. (canceled)

32. A device according to claim 24, wherein the anti-feathering elements cover up to 15% of each extended edge region.

33.-35. (canceled)

36. A device according to claim 24, wherein the device further includes a first opacification layer superposed with at least a portion of the substrate, the first opacifying layer having a window revealing the discontinuous image, wherein the image layer and the first opacifying layer are formed on a first side of the substrate from the same printed material in a same rotary printing action.

37. A device according to claim 24, wherein the device further includes a first opacification layer superposed with at least a portion of the substrate, wherein the image layer and the first opacifying layer are formed on a first side of the substrate from different printed materials in separate rotary printing actions.

38.-40. (canceled)

41. A device according to claim 37, wherein the first opacifying layer includes a window revealing the discontinuous image.

42. (canceled)

43. A device according to claim 24, wherein the discontinuous image includes a plurality of image elements, the device further including:
focusing elements formed in or on the substrate, the focusing elements causing the image elements to be sampled so as to project imagery which is observable to a user from at least a first viewing angle,
wherein
the plurality of anti-feathering elements in each extended edge region include design parameters selected to minimise moiré magnification effects when sampled by the focusing elements.

44.-45. (canceled)

46. A device according to claim 25, wherein the device is a micro-optic device for producing optical effects and the substrate is transparent or translucent.

47. A security document including a device according to claim 24.
